(19) United States
(12) Patent Application Publication
(10) Pub. No.: US 2006/0228870 A1
(43) Pub. Date: Oct. 12, 2006

(54) Method of making group III-V nitride-based semiconductor crystal

(75) Inventor: Yuichi Oshima, Tsuchiura (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: Hitachi Cable, Ltd., Tokyo (JP)

(21) Appl. No.: 11/182,074

(22) Filed: Jul. 15, 2005

(30) Foreign Application Priority Data
Apr. 8, 2005 (JP) 2005-112767

(51) Int. Cl. H01L 21/30; H01L 21/20

(52) U.S. Cl. 438/458; 438/483

(57) ABSTRACT

A method of making a group III-V nitride-based semiconductor crystal has: a first step of providing a first semiconductor crystal substrate; a second step of growing a first group III-V nitride-based semiconductor crystal on the first semiconductor crystal substrate in a first crystal axis direction until when reaching a first thickness; a third step of cutting the first group III-V nitride-based semiconductor crystal along a cutting plane parallel to a propagation direction with a highest threading dislocation density existing inside of the first group III-V nitride-based semiconductor crystal; and a fourth step of growing a second group III-V nitride-based semiconductor crystal on the cutting plane of the first group III-V nitride-based semiconductor crystal until when reaching a second thickness. The second group III-V nitride-based semiconductor crystal is provided as the group III-V nitride-based semiconductor crystal.

The present application is based on Japanese patent application No. 2005-112767, the entire contents of which are incorporated herein by reference.

### BACKGROUND OF THE INVENTION

1. Field of the Invention

This invention relates to a method of making a group III-V nitride-based semiconductor crystal.

2. Description of the Related Art

GaN-based compound semiconductors such as gallium nitride (GaN), indium gallium nitride (InGaN) and aluminum gallium nitride (AlGaN) attract attention for a material of blue light emitting diode (LED) or laser diode (LD) . Further, since the GaN-based compound semiconductors have a good heat resistance and environment resistance, they have begun to be applied to other electronic devices.

At present, a substrate used widely to grow GaN is sapphire. In general, a method is used in which GaN is epitaxially grown on a sapphire single crystal substrate by MOVPE (metalorganic vapor phase epitaxy) etc.

However, since the sapphire substrate mismatches in lattice constant with the GaN, a GaN single crystal cannot be grown directly on the sapphire substrate. Therefore, a method is disclosed in which a buffer layer (=low-temperature growth buffer layer) of AlN or GaN is grown on the sapphire substrate at a low temperature to buffer strain in lattice and then GaN is grown thereon (e.g., Japanese patent Nos. 3026087 and 2751963 and Japanese patent publication No. 8-8217).

By using the low-temperature growth buffer layer, the epitaxial growth of GaN single crystal can be realized. However, the above method still has a problem that the grown GaN has a number of defects since the lattice mismatch between the substrate and the GaN is not eliminated. It is presumed that the defect brings some failure to a manufacture of GaN-based LD.

Under the circumstances, it is desired to develop a GaN self-standing substrate. Since it is difficult to grow a large ingot of GaN from melt unlike Si or GaAs, various methods such as the ultrahigh temperature and pressure method, flux method and HVPE (hydride vapor phase epitaxy) have been tried to make the GaN self-standing substrate.

A typical method for making a nitride semiconductor self-standing substrate is conducted such that a GaN thick film is grown on a hetero-substrate such as sapphire by HVPE and then the hetero-substrate is removed to obtain a GaN self-standing substrate (e.g., JP-A-2003-178984). In this method, a void-containing layer functions as a strain buffering layer so as to buffer a strain caused by a difference in lattice constant or thermal expansion coefficient between the underlying substrate and the group III nitride semiconductor layer grown thereon. By the method, a substrate of group III nitride semiconductor can be obtained which offers a reduced defect density and a good crystalline quality without warping. Further, the self-standing substrate thus obtained can be easily separated. Based on the method, GaN substrates with a reduced dislocation have begun to be commercially available.

However, a large practical GaN single crystal with a high crystalline quality has never been developed even in the above methods.

In the ultrahigh temperature and pressure method, which needs tens of thousands of atmospheres and thousands of degrees, it is difficult to grow a large crystal. Therefore, it only can provide a GaN crystal with a diameter of several millimeters and a thickness of several tens of micrometers.

In the flux method, although it only needs hundreds of atmospheres and about a thousand degrees, it only can provide a GaN crystal with a diameter of several millimeters and a thickness of several tens of micrometers. In addition, there are problems that removal of nitrogen occurs and Na or Ca flux is diffused into the crystal. Furthermore, since it is difficult to control the generation of crystal nuclei at initial growth, polycrystal may be contained.

In the HVPE method, a crystal with a diameter of about 5.08 cm (=2 inches) has been developed. However, due to the hetero-epitaxial growth using a hetero-substrate, number of dislocations must be generated at the initial growth interface. To solve this problem, dislocation reducing techniques have been developed. One example is ELO (epitaxial lateral overgrowth) in which a stripe mask of a dielectric material such as SiO₂ is formed on a GaN layer on a sapphire substrate and GaN is grown again on the mask. However, even when the ELO is used, there must be generated a dislocation density as high as 1×10⁶ cm⁻². This impedes improvement in device property.

### SUMMARY OF THE INVENTION

It is an object of the invention to provide a method of making a group III-V nitride-based semiconductor crystal that can offer a significantly reduced dislocation density.

(1) According to one aspect of the invention, a method of making a group III-V nitride-based semiconductor crystal comprises:

a first step of providing a first semiconductor crystal substrate;

a second step of growing a first group III-V nitride-based semiconductor crystal on the first semiconductor crystal substrate in a first crystal axis direction until when reaching a first thickness;

a third step of cutting the first group III-V nitride-based semiconductor crystal along a cutting plane parallel to a propagation direction with a highest threading dislocation density existing inside of the first group III-V nitride-based semiconductor crystal; and

a fourth step of growing a second group III-V nitride-based semiconductor crystal on the cutting plane of the first group III-V nitride-based semiconductor crystal until when reaching a second thickness,

wherein the second group III-V nitride-based semiconductor crystal is provided as the group III-V nitride-based semiconductor crystal.

(i) It is preferred that after the fourth step, the same steps as the third to the fourth steps are repeated at least one time, and a group III-V nitride-based semiconductor crystal to be finally grown after the repetition is provided as the group III-V nitride-based semiconductor crystal.

(ii) It is preferred that the first semiconductor crystal substrate is a hetero-substrate that has a composition different from the first group III-V nitride-based semiconductor crystal, and the first group III-V nitride-based semiconductor crystal is grown on the hetero-substrate through a buffer layer.

(iii) It is also preferred that the first semiconductor crystal substrate is a seed crystal substrate that has the same composition as the first group III-V nitride-based semiconductor crystal.

(iv) It is preferred that at least one of the first and second group III-V nitride-based semiconductor crystals is grown by ELO using a mask layer with an opening.

(v) It is preferred that the first and second group III-V nitride-based semiconductor crystals have a composition of InₓAl_{y}Ga_{1-x-y}N (x≧0, y≧0, x+y≦1).

(2) According to another aspect of the invention, a method of making a group III-V nitride-based semiconductor substrate comprises the steps of:

growing an ingot by using as a seed crystal the group III-V nitride-based semiconductor crystal as described earlier in (1),

slicing the ingot into plural substrates; and

polishing both faces of each of the plural substrates to provide the group III-V nitride-based semiconductor substrate.

(vi) It is preferred that said ingot growing step is conducted by using as a seed crystal the group III-V nitride-based semiconductor crystal to be finally grown after the repetition as described earlier in (i).

(3) According to another aspect of the invention, a method of making a group III-V nitride-based semiconductor crystal comprising:

providing a semiconductor crystal substrate;

growing a first group III-V nitride-based semiconductor crystal on the semiconductor crystal substrate in a crystal axis direction;

cutting the first group III-V nitride-based semiconductor crystal along a cutting plane parallel to a propagation direction with a highest threading dislocation density existing inside of the first group III-V nitride-based semiconductor crystal; and

growing the group III-V nitride-based semiconductor crystal on the cutting plane of the first group III-V nitride-based semiconductor crystal,

wherein the group III-V nitride-based semiconductor crystal has a dislocation density of less than 1×10⁶ cm⁻².

<Solutions of the Invention>

The invention is featured in that a plurality of growths are conducted while changing its growth direction in the growth of nitride semiconductor by HVPE (hydride vapor phase epitaxy) to prevent the propagation of a dislocation to provide a group II I-V nitride-based semiconductor crystal with a significantly reduced dislocation density.

As described earlier, the ELO technique is well known. The ELO is conducted such that a stripe mask with windows alternately opened at intervals of several microns is formed on a substrate, a crystal is grown through the windows and then laterally grown over the mask. Since no dislocation is propagated in the lateral growth direction, a region with a width of about ten micrometers can be formed at a low dislocation density. The ultimate ELO is such that the entire surface of a substrate with a diameter of 5.08 cm (=2 inches) is covered with a mask, a small window in nanometers is formed at the central portion, and a crystal is grown through the small window over the entire 2-inch surface by the lateral growth.

By such a method, a wafer with no dislocation can be obtained theoretically. However, it is impossible in practice. If the mask width exceeds a surface diffusion length of source seed, a polycrystal must be generated on the mask. This can be avoided by using no mask. However, it is not practical to conduct a bulk crystal growth by using a microscopic crystal as a seed.

The inventor has invented a method as described below. First, for example a c-face GaN self-standing substrate with a diameter of 5.08 cm (=2 inches) is provided. This substrate can be prepared by using, for example, the void-formed separation method (as disclosed in JP-A-2003-18984, the entire contents of which are herein incorporated by reference). Second, it is grown up to a thickness of 2 inches or more. Third, it is cut off in a vertical direction. Thereby, a cutting plane with a diameter of 5.08 cm (=2 inches) can be obtained. The cutting can be conducted by cleavage or using a wire saw. Fourth, using the cutting plane as a new growth surface, a crystal is grown again up to a thickness of 5.08 cm (=2 inches).

The above method is a macroscopic lateral growth whereas the ELO is a microscopic lateral growth. Thus, the method is still the lateral growth and can significantly improve the dislocation density. BY slicing a crystal obtained by the method to have a desired crystal face and polishing it, a wafer with a high quality can be obtained.

However, it is necessary to pay attention to the cutting direction in the third process. In fact, it is not always desirable to cut it just in the vertical direction (i.e., in parallel to a c-axis). This is because the propagation direction of a threading dislocation is not parallel to the c-axis exactly.

FIG. 3 is photographs showing a CL (cathode luminescence) image in a cross section of a GaN self-standing substrate. A dislocation part is nonradiative recombination center and, therefore, it becomes dark in contrast as compared to a part without dislocation. It should be noted that a dislocation is seen like a small dot. Since this cross section is a cleaved surface parallel to the c-axis, if a dislocation is parallel to the c-axis, it must be seen like a line extending vertically. Namely, the dislocation seen like a dot indicates that it is not parallel to the c-axis.

Since a GaN thin template on a sapphire substrate with a very high dislocation density as used in typical ELO has a dislocation extending in a c-axis direction, the dislocation reducing effect can be obtained by conducting the lateral growth in a c-face direction. However, if a dislocation is not parallel to the c-axis, when a crystal is grown on a cross section cut parallel to the c-axis, the dislocation may be still propagated in its original direction. Thus, in order to maximize the lateral growth effect, it is important that the cutting is conducted to allow the cutting plane to be parallel to a dislocation line. Of course, the propagation direction of dislocation is not limited to one direction. In hexagonal crystal GaN, it is assumed that a dislocation can be propagated in six directions equivalent crystallographically. Therefore, it is desirable that the lateral growth is repeated six times in the six directions in the case of hexagonal GaN.

Although this appears to be a costly growth method, it is not so costly in fact. Because, once a high-quality wafer is obtained, a crystal only has to be simply grown on the wafer as a seed in one direction and sliced to provide a target self-standing substrate. Therefore, troublesome processes need not be conducted.

<Advantages of the Invention>

In the invention, in growing a nitride semiconductor by HVPE, plural growths are performed while suitably changing the growth direction. Thereby, the propagation of dislocation can be prevented to provide a group III-V nitride-based semiconductor crystal with a significantly reduced dislocation density. The reduction of dislocation density is very dramatic. Due to the method of the invention, the dislocation density can be several orders of magnitude reduced to a 2×10² cm⁻² to 5×10² cm⁻² whereas there exists a dislocation density of about 1×10⁶ cm⁻² in the conventional dislocation reducing techniques such as ELO.

Once a high-quality group III-V nitride-based semiconductor crystal is obtained, an ingot can be made by simply growing a crystal in one direction on the obtained crystal as a seed. From the ingot, a number of substrates can be cut off.

### BRIEF DESCRIPTION OF THE DRAWINGS

The preferred embodiments according to the invention will be explained below referring to the drawings, wherein:

FIGS. 1A to 1I are illustrative perspective views showing of a method of making a group III-V nitride-based semiconductor crystal in a first preferred embodiment according to the invention;

FIGS. 2A to 2I are illustrative perspective views showing of a method of making a group III-V nitride-based semiconductor crystal in a second preferred embodiment according to the invention; and

FIG. 3 is photographs showing a CL (cathode luminescence) image in a cross section of a GaN self-standing substrate.

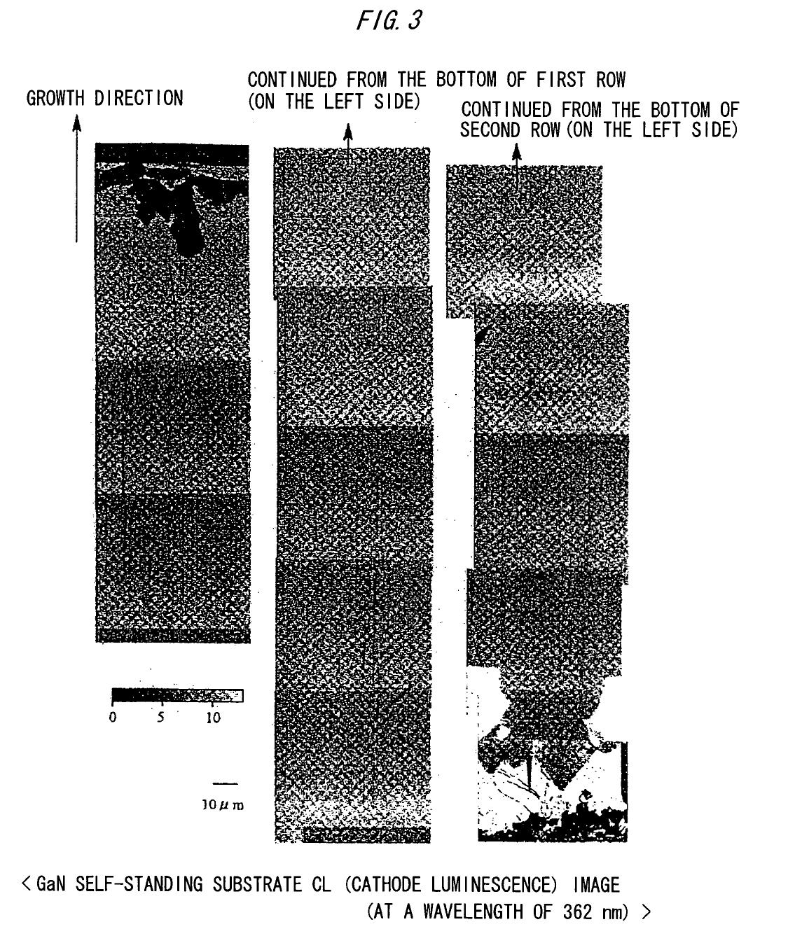

### DETAILED DESCRIPTION OF THE PREFERRED EMBODIMENTS

### Embodiment 1

At first, a c-face sapphire single crystal substrate with a diameter of 60 mm and a thickness of 330 μm is provided.

Then, a 300 nm thick GaN thin film is formed on the sapphire substrate by MOVPE (metalorganic vapor phase epitaxy. Then, a 20 nm thick Ti layer is formed thereon in vacuum deposition. Then, it is thermally treated in carrier gas of H₂:NH₃=4:1 at 1060° C. for 30 min. Thereby, the Ti layer is nitrided into a TiN layer and formed into mesh-like structure with a number of fine holes of tens of nanometers. On the other hand, the GaN thin film is etched to have therein voids reaching to the sapphire substrate.

Then, the void-formed substrate is placed in an HVPE (hydride vapor phase epitaxy) furnace and a 600 μm thick GaN thick film is grown thereon by HVPE.

In a cooling process after completing the growth, the GaN thick film is by itself separated due to a thermal stress caused by a difference in thermal expansion coefficient between the sapphire and the GaN. By polishing both faces thereof, a GaN self-standing substrate (=seed crystal 1) with a thickness of 430 μm is obtained.

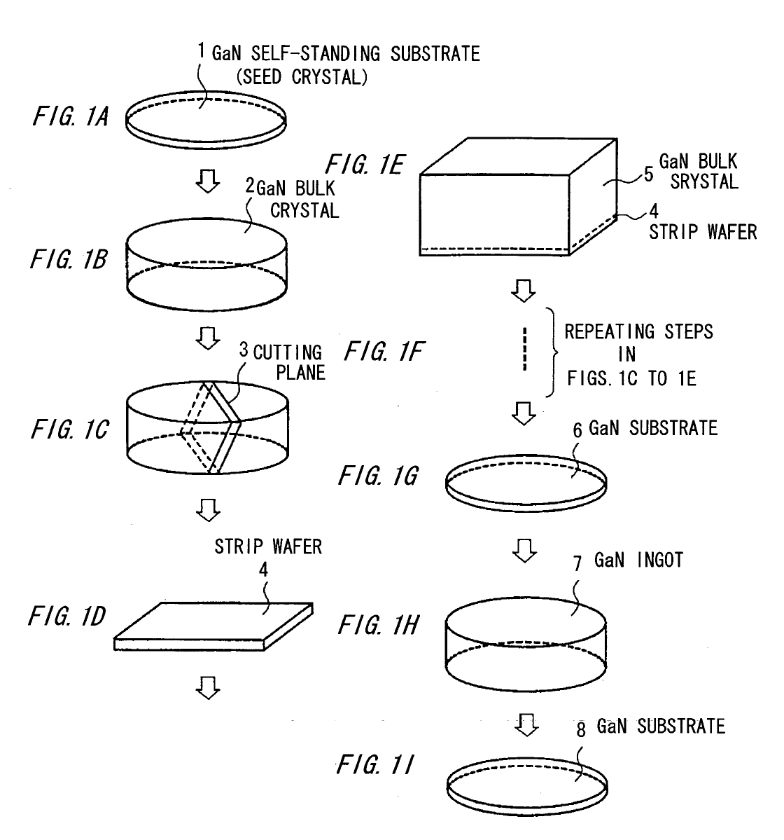

The process of the first embodiment using the seed crystal 1 thus obtained will be explained below referring to FIGS. 1A to 1I.

(1) The self-standing substrate as the seed crystal 1 (=first semiconductor crystal substrate defined in attached claims) obtained as described above is provided (FIG. 1A, step 1). It is placed in the HVPE furnace, and GaN (=first group III-V nitride-based semiconductor crystal defined in attached claims) is grown up to a thickness of 24 mm (=first thickness defined in attached claims), thereby obtaining a GaN bulk crystal 2 (FIG. 1B, step 2).

As the result of a CL observation in cross section of a seed crystal grown under the same conditions as mentioned above, dislocation is propagated in parallel to (1-101) plane and its equivalent plane.

(2) Then, the GaN bulk crystal 2 grown in step 2 is cut at a cutting plane 3 parallel to the (1-101) plane (FIG. 1C, step 3) and formed into a strip wafer 4 with dimensions of 58×25×t0.43 mm (FIG. 1D, step 4).

(3) Then, the strip wafer 4 cut off in step 4 is placed in the HVPE furnace, and GaN (=second group III-V nitride-based semiconductor crystal defined in attached claims) is grown on the strip wafer 4, I.e., on the cutting plane 3 of the bulk crystal 2, up to a thickness of 24 mm (=second thickness defined in attached claims), thereby obtaining a GaN bulk crystal 5 (FIG. 1E, step 5).

(4) Then, with respect to five other planes in six directions equivalent crystallographically in hexagonal GaN, the same steps as steps 3 to 5 (as shown in FIGS. 1C to 1E) are repeated (FIG. 1F, step 6). However, in the final growth, it is grown to have a thickness (=second thickness) of 55 mm.

(5) Then, from the crystal obtained in step 6, a GaN substrate 6 with a diameter of 5.08 cm (=2 inches) and a thickness of 430 μm is cut off while rendering its main plane c-face (FIG. 1G, step 7).

(6) Then, the wafer (=GaN substrate 6) obtained in step 7 is placed in the HVPE furnace, and GaN is grownup to a thickness of 40 mm, thereby obtaining a GaN ingot 7 (FIG. 1H, step 8.

(7) Then, the ingot 7 obtained in step 8 is sliced into a GaN substrate 8 with a diameter of 5.08 cm (=2 inches) and a thickness of 430 μm (FIG. 1I, step 9).

Three of the GaN substrates 8 obtained are cut off at the head, tail and intermediate portions the ingot 7, and dislocation of them is measured by cathode luminescence. As a result, all of them have a dislocation density as low as 5×10² cm⁻². Thus, it can be assumed that other wafers have reduced dislocation density as well since all the three wafers have the same dislocation density.

### Embodiment 2: combination with ELO

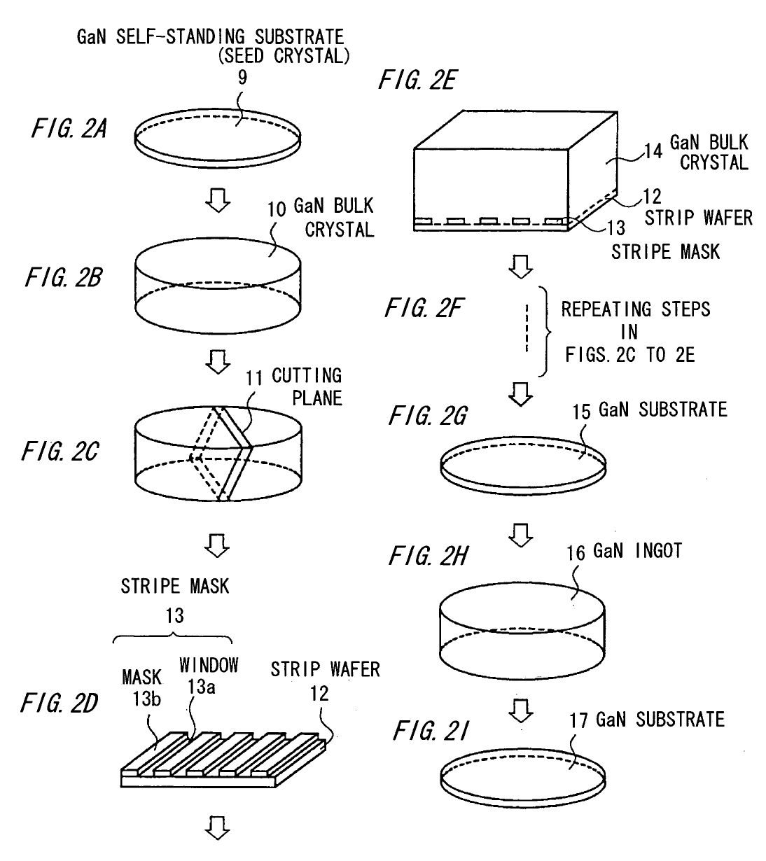

The process of the second embodiment using the ELO technique in combination with the above process of the first embodiment will be explained below referring to FIGS. 2A to 2I.

(1) A self-standing substrate as a seed crystal 9 (=first semiconductor crystal substrate defined in attached claims) obtained is provided like the self-standing substrate 1 of the first embodiment (FIG. 2A, step 1). It is placed in the HVPE furnace, and GaN (=first group III-V nitride-based semiconductor crystal defined in attached claims) is grown up to a thickness of 24 mm (=first thickness defined in attached claims), thereby obtaining a GaN bulk crystal 10 (FIG. 2B, step 2).

As the result of a CL observation in cross section of a seed crystal grown under the same conditions as mentioned above, dislocation is propagated in parallel to (1-101) plane and its equivalent plane.

(2) Then, the GaN bulk crystal 10 grown in step 2 is cut at a cutting plane 11 parallel to the (1-101) plane (FIG. 2C, step 3) and formed into a strip wafer 12 with dimensions of 58×25×t0.43 mm (FIG. 2D).

Using the ELO technique, SiO₂ film is 0.5 μm deposited on the surface of the strip wafer 12 by thermal CVD, 3 μm wide stripe windows 13a are opened in the SiO₂ film by photolithography to form a stripe mask 13 with a 7 μm wide mask 13b. (FIG. 2D, step 4)

(3) Then, the strip wafer 12 fabricated in step 4 is placed in the HVPE furnace, and GaN (=second group III-V nitride-based semiconductor crystal defined in attached claims) is grown on the strip wafer 12, I.e., on the cutting plane 11 of the bulk crystal 10, up to a thickness of 24 mm (=second thickness defined in attached claims), thereby obtaining a GaN bulk crystal 14 (FIG. 2E, step 5).

(4) Then, with respect to five other planes in six directions equivalent crystallographically in hexagonal GaN, the same steps as steps 3 to 5 (as shown in FIGS. 2C to 2E) are repeated (FIG. 2F, step 6). However, in the final growth, it is grown to have a thickness (=second thickness) of 55 mm.

(5) Then, from the crystal obtained in step 6, a GaN substrate 15 with a diameter of 5.08 cm (=2 inches) and a thickness of 430 μm is cut off while rendering its main plane A-face (FIG. 2G, step 7).

(6) Then, the wafer (=GaN substrate 15) obtained in step 7 is placed in the HVPE furnace, and GaN is grown up to a thickness of 40 mm, thereby obtaining a GaN ingot 16 (FIG. 2H, step 8.

(7) Then, the ingot 16 obtained in step 8 is sliced into a GaN substrate 17 with a diameter of 5.08 cm (=2 inches) and a thickness of 430 μm (FIG. 2I, step 9).

Three of the GaN substrates 17 obtained are cut off at the head, tail and intermediate portions the ingot 16, and dislocation of them is measured by cathode luminescence. As a result, all of them have a dislocation density as low as 2×10² cm⁻². This may be caused by that the propagation of dislocation is further prevented by the SiO₂ stripe mask 13. Thus, it can be assumed that other wafers have reduced dislocation density as well since all the three wafers have the same dislocation density.

### Other Embodiments and Modifications

Although in the above embodiments the c-face or A-face substrate is obtained finally, a substrate of an arbitrary orientation may be finally cut off according to use.

Although in the above embodiments the ELO using the SiO₂ mask is used in combination, other mask materials such as SiN may be used or another dislocation reducing method such as PENDEO epitaxy may be used in combination.

In the above embodiments, the seed crystal as the first semiconductor crystal substrate is made of GaN, the same as the first group III-V nitride-based semiconductor crystal. However, the seed-crystal substrate may be different from the first group III-V nitride-based semiconductor crystal. In this case, it is desired that the first group III-V nitride-based semiconductor crystal is grown on a hetero-substrate through a buffer layer.

Although the invention has been described with respect to the specific embodiments for complete and clear disclosure, the appended claims are not to be thus limited but are to be construed as embodying all modifications and alternative constructions that may occur to one skilled in the art which fairly fall within the basic teaching herein set forth.

What is claimed is:

1. A method of making a group III-V nitride-based semiconductor crystal comprising:
a first step of providing a first semiconductor crystal substrate;
a second step of growing a first group III-V nitride-based semiconductor crystal on the first semiconductor crystal substrate in a first crystal axis direction until when reaching a first thickness;
a third step of cutting the first group III-V nitride-based semiconductor crystal along a cutting plane parallel to a propagation direction with a highest threading dislocation density existing inside of the first group III-V nitride-based semiconductor crystal; and
a fourth step of growing a second group III-V nitride-based semiconductor crystal on the cutting plane of the first group III-V nitride-based semiconductor crystal until when reaching a second thickness,
wherein the second group III-V nitride-based semiconductor crystal is provided as the group III-V nitride-based semiconductor crystal.

2. The method according to claim 1, wherein:
after the fourth step, the same steps as the third to the fourth steps are repeated at least one time, and
a group III-V nitride-based semiconductor crystal to be finally grown after the repetition is provided as the group III-V nitride-based semiconductor crystal.

3. The method according to claim 1, wherein:
the first semiconductor crystal substrate is a hetero-substrate that has a composition different from the first group III-V nitride-based semiconductor crystal, and the first group III-V nitride-based semiconductor crystal is grown on the hetero-substrate through a buffer layer.

4. The method according to claim 2, wherein:
the first semiconductor crystal substrate is a hetero-substrate that has a composition different from the first group III-V nitride-based semiconductor crystal, and the first group III-V nitride-based semiconductor crystal is grown on the hetero-substrate through a buffer layer.

5. The method according to claim 1, wherein:
the first semiconductor crystal substrate is a seed crystal substrate that has the same composition as the first group III-V nitride-based semiconductor crystal.

6. The method according to claim 2, wherein:
the first semiconductor crystal substrate is a seed crystal substrate that has the same composition as the first group III-V nitride-based semiconductor crystal.

7. The method according to claim 1, wherein:
at least one of the first and second group III-V nitride-based semiconductor crystals is grown by ELO using a mask layer with an opening.

8. The method according to claim 1, wherein:
the first and second group III-V nitride-based semiconductor crystals have a composition of InₓAl_{y}Ga_{1-x-y}N (x≧0, y≧0, x+y≦1).

9. A method of making a group III-V nitride-based semiconductor substrate, comprising the steps of:
growing an ingot by using as a seed crystal the group III-V nitride-based semiconductor crystal as defined in claim 1,
slicing the ingot into plural substrates; and
polishing both faces of each of the plural substrates to provide the group III-V nitride-based semiconductor substrate.

10. The method according to claim 9, wherein:
said ingot growing step is conducted by using as a seed crystal the group III-V nitride-based semiconductor crystal to be finally grown after the repetition as defined in claim 2.

11. A method of making a group III-V nitride-based semiconductor crystal comprising:
providing a semiconductor crystal substrate;
growing a first group III-V nitride-based semiconductor crystal on the semiconductor crystal substrate in a crystal axis direction;
cutting the first group III-V nitride-based semiconductor crystal along a cutting plane parallel to a propagation direction with a highest threading dislocation density existing inside of the first group III-V nitride-based semiconductor crystal; and
growing the group III-V nitride-based semiconductor crystal on the cutting plane of the first group III-V nitride-based semiconductor crystal,
wherein the group III-V nitride-based semiconductor crystal has a dislocation density of less than 1×10⁶ cm⁻².
